(19) United States
(12) Patent Application Publication
(10) Pub. No.: US 2026/0088783 A1
(43) Pub. Date: Mar. 26, 2026

(54) CURRENT FEEDBACK AMPLIFIERS FOR LOAD MODULATED ENVELOPE TRACKING

(71) Applicant: Skyworks Solutions, Inc., Irvine, CA (US)

(72) Inventor: David Steven Ripley, Cedar Rapids, IA (US)

(21) Appl. No.: 19/328,702

(22) Filed: Sep. 15, 2025

Related U.S. Application Data
(60) Provisional application No. 63/697,014, filed on Sep. 20, 2024.

(51) Int. Cl. H03F 3/24; H03F 1/02; H03F 1/08; H03F 3/45; H04B 1/40

(52) U.S. Cl. CPC H03F 3/245; H03F 1/0211; H03F 1/086; H03F 3/45183; H04B 1/40; H03F 2200/102; H03F 2200/451

(57) ABSTRACT

Current feedback amplifiers for load modulated envelope tracking are disclosed. In certain embodiments, a load modulated power amplifier for amplifying a radio frequency (RF) signal includes a controllable capacitor for adjusting the power amplifier's load impedance and an envelope control amplifier for controlling a capacitance value of the controllable capacitor based on an envelope signal indicating an envelope of the RF signal. The envelope control amplifier includes an input transconductance stage that receives the envelope signal, a current feedback amplifier having an input electrically connected to an output of the input transconductance stage and an output that controls the controllable capacitor, and a feedback resistor electrically connected between the output of the current feedback amplifier and the input of the current feedback amplifier.

### CROSS-REFERENCE TO RELATED APPLICATIONS

This application claims the benefit of priority under 35 U.S.C. § 119 of U.S. Provisional Patent Application No. 63/697,014, filed Sep. 20, 2024 and titled “CURRENT FEEDBACK AMPLIFIERS FOR LOAD MODULATED ENVELOPE TRACKING,” which is herein incorporated by reference in its entirety.

### BACKGROUND

### Field

Embodiments of the invention relate to electronic systems, and in particular, to radio frequency electronics.

### Description of Related Technology

Radio frequency (RF) communication systems can be used for transmitting and/or receiving signals of a wide range of frequencies. For example, an RF communication system can be used to wirelessly communicate RF signals in a frequency range of about 30 kHz to 300 GHz, such as in the range of about such as in the range of about 400 MHz to about 7.125 GHz for Frequency Range 1 (FR1) of the Fifth Generation (5G) communication standard or in the range of about 24.250 GHz to about 71.000 GHz for Frequency Range 2 (FR2) of the 5G communication standard.

Examples of RF communication systems include, but are not limited to, mobile phones, tablets, base stations, network access points, customer-premises equipment (CPE), laptops, and wearable electronics.

### SUMMARY

In certain embodiments, a load modulated power amplifier is disclosed. The load modulated power amplifier includes an input terminal configured to receive a radio frequency signal and an output terminal configured to provide an amplified radio frequency signal, a controllable capacitor, a pair of amplifiers including a first amplifier and a second amplifier, an output balun having a primary winding electrically connected between an output of the first amplifier and an output of the second amplifier and a secondary winding electrically connected between the output terminal and the controllable capacitor, and an envelope control amplifier including an input transconductance stage configured to receive an envelope signal indicating an envelope of the radio frequency signal, a current feedback amplifier having an input electrically connected to an output of the input transconductance stage and an output configured to control the controllable capacitor, and a feedback resistor electrically connected between the output of the current feedback amplifier and the input of the current feedback amplifier.

In various embodiments, the envelope signal is differential, the input transconductance stage having a first input and a second input that differentially receive the envelope signal. According to a number of embodiments, the input transconductance stage provides a differential to single-ended conversion. In accordance with several embodiments, the input transconductance stage includes a first input transistor having a gate electrically connected to the first input, a second input transistor having a gate electrically connected to the second input, a first resistor electrically connected between a source of the first input transistor and a tail node, and a second resistor electrically connected between a source of the second input transistor and the tail node.

In some embodiments, the current feedback amplifier includes an n-type input transistor having a source electrically connected to the input of the current feedback amplifier and a p-type input transistor having a source electrically connected to the input of the current feedback amplifier. According to a number of embodiments, the current feedback amplifier further includes a current mirror having an input electrically connected to a drain of the n-type input transistor. In accordance with several embodiments, the current mirror includes a p-type mirror transistor having a drain electrically connected to the drain of the n-type input transistor, and a n-type mirror transistor having a gate electrically connected to the drain of the p-type mirror transistor and a source electrically connected to a gate of the p-type mirror transistor. According to various embodiments, the p-type mirror transistor is an enhancement-mode transistor, and the n-type mirror transistor is a depletion-mode transistor. In accordance with a number of embodiments, the current feedback amplifier further includes a n-type output transistor having a gate electrically connected to an output of the current mirror and a source electrically connected to the output of the current feedback amplifier. According to several embodiments, a gate capacitance of the n-type output transistor serves as a frequency compensation capacitor for a feedback loop of the current feedback amplifier.

In various embodiments, the current feedback amplifier further includes a reference input configured to receive a reference voltage that controls a DC bias voltage of the input of the current feedback amplifier. According to a number of embodiments, the load modulated power amplifier further includes a digital-to-analog converter configured to generate the reference voltage based on a digital control signal. In accordance with several embodiments, the current feedback amplifier includes a p-type input transistor, an n-type input transistor, a first gate bias circuit configured to bias a gate of the p-type input transistor based on the reference voltage, and a second gate bias circuit configured to bias a gate of the n-type input transistor based on the reference voltage.

In some embodiments, the load modulated power amplifier further includes a second feedback resistor electrically connected between a second output of the current feedback amplifier and the input of the current feedback amplifier, one of the feedback resistor or the second feedback resistor selectively activated based on a band select signal.

In various embodiments, the load modulated power amplifier further includes a driver amplifier having an input electrically connected to the input terminal and an input balun having a first winding electrically connected to an output of the driver amplifier and a second winding electrically connected between an input of the first amplifier and an input of the second amplifier.

In several embodiments, the load modulated power amplifier further includes a bias circuit configured to adjust a bias of at least one of the first amplifier or the second amplifier based on an output voltage of the envelope control amplifier.

In certain embodiments, the present disclosure relates to a mobile device. The mobile device includes a driver configured to generate a radio frequency signal and a front-end system including a load modulated power amplifier having an input terminal configured to receive the radio frequency signal and an output terminal configured to provide an amplified radio frequency signal. The load modulated power amplifier includes a controllable capacitor, a pair of amplifiers including a first amplifier and a second amplifier, an output balun having a primary winding electrically connected between an output of the first amplifier and an output of the second amplifier and a secondary winding electrically connected between the output terminal and the controllable capacitor, and an envelope control amplifier including an input transconductance stage configured to receive an envelope signal indicating an envelope of the radio frequency signal, a current feedback amplifier having an input electrically connected to an output of the input transconductance stage and an output configured to control the controllable capacitor, and a feedback resistor electrically connected between the output of the current feedback amplifier and the input of the current feedback amplifier.

In some embodiments, the envelope signal is differential, the input transconductance stage having a first input and a second input that differentially receive the envelope signal. According to a number of embodiments, the input transconductance stage provides a differential to single-ended conversion. In accordance with several embodiments, the input transconductance stage includes a first input transistor having a gate electrically connected to the first input, a second input transistor having a gate electrically connected to the second input, a first resistor electrically connected between a source of the first input transistor and a tail node, and a second resistor electrically connected between a source of the second input transistor and the tail node.

In several embodiments, the current feedback amplifier includes an n-type input transistor having a source electrically connected to the input of the current feedback amplifier and a p-type input transistor having a source electrically connected to the input of the current feedback amplifier. According to a number of embodiments, the current feedback amplifier further includes a current mirror having an input electrically connected to a drain of the n-type input transistor. In accordance with various embodiments, the current mirror includes a p-type mirror transistor having a drain electrically connected to the drain of the n-type input transistor, and a n-type mirror transistor having a gate electrically connected to the drain of the p-type mirror transistor and a source electrically connected to a gate of the p-type mirror transistor. According to some embodiments, the p-type mirror transistor is an enhancement-mode transistor, and the n-type mirror transistor is a depletion-mode transistor.

In various embodiments, the current feedback amplifier further includes a n-type output transistor having a gate electrically connected to an output of the current mirror and a source electrically connected to the output of the current feedback amplifier. According to a number of embodiments, a gate capacitance of the n-type output transistor serves as a frequency compensation capacitor for a feedback loop of the current feedback amplifier.

In several embodiments, the current feedback amplifier further includes a reference input configured to receive a reference voltage that controls a DC bias voltage of the input of the current feedback amplifier. According to a number of embodiments, the envelope control amplifier further includes a digital-to-analog converter configured to generate the reference voltage based on a digital control signal. In accordance with various embodiments, the current feedback amplifier includes a p-type input transistor, an n-type input transistor, a first gate bias circuit configured to bias a gate of the p-type input transistor based on the reference voltage, and a second gate bias circuit configured to bias a gate of the n-type input transistor based on the reference voltage.

In some embodiments, the envelope control amplifier further includes a second feedback resistor electrically connected between a second output of the current feedback amplifier and the input of the current feedback amplifier, one of the feedback resistor or the second feedback resistor selectively activated based on a band select signal.

In various embodiments, the load modulated power amplifier further includes a driver amplifier having an input electrically connected to the input terminal and an input balun having a first winding electrically connected to an output of the driver amplifier and a second winding electrically connected between an input of the first amplifier and an input of the second amplifier.

In several embodiments, the load modulated power amplifier further includes a bias circuit configured to adjust a bias of at least one of the first amplifier or the second amplifier based on an output voltage of the envelope control amplifier.

In some embodiments, the transceiver is configured to generate the envelope signal.

In various embodiments, the front-end system further includes a band switch electrically connected to the output terminal. According to a number of embodiments, the mobile device further includes an antenna electrically connected to the band switch.

In certain embodiments, the present disclosure relates to a method of amplification in a load modulation power amplifier. The method includes amplifying a radio frequency signal received at an input terminal using a pair of amplifiers, the pair of amplifiers including a first amplifier and a second amplifier, outputting an amplified radio frequency signal to a balun that incudes a primary winding electrically connected between an output of the first amplifier and an output of the second amplifier and a secondary winding electrically connected between an output terminal and a controllable capacitor, receiving an envelope signal indicating an envelope of the radio frequency signal at an input transconductance stage of an envelope control amplifier, controlling the controllable capacitor using an output of a current feedback amplifier of the envelope control amplifier, the input transconductance stage having an output electrically connected to an input of the current feedback amplifier, and providing current feedback using a feedback resistor electrically connected between the output of the current feedback amplifier and the input of the current feedback amplifier.

In some embodiments, the envelope signal is differential, the input transconductance stage having a first input and a second input that differentially receive the envelope signal. According to a number of embodiments, the method further includes providing a differential to single-ended conversion using the input transconductance stage. In accordance with several embodiments, the input transconductance stage includes a first input transistor having a gate electrically connected to the first input, a second input transistor having a gate electrically connected to the second input, a first resistor electrically connected between a source of the first input transistor and a tail node, and a second resistor electrically connected between a source of the second input transistor and the tail node. According to various embodiments, the current feedback amplifier includes an n-type input transistor having a source electrically connected to the input of the current feedback amplifier and a p-type input transistor having a source electrically connected to the input of the current feedback amplifier. In accordance with several embodiments, the current feedback amplifier further includes a current mirror having an input electrically connected to a drain of the n-type input transistor. According to various embodiments, the current mirror includes a p-type mirror transistor having a drain electrically connected to the drain of the n-type input transistor, and a n-type mirror transistor having a gate electrically connected to the drain of the p-type mirror transistor and a source electrically connected to a gate of the p-type mirror transistor. In according to several embodiments, the p-type mirror transistor is an enhancement-mode transistor, and the n-type mirror transistor is a depletion-mode transistor. According to several embodiments, the current feedback amplifier further includes a n-type output transistor having a gate electrically connected to an output of the current mirror and a source electrically connected to the output of the current feedback amplifier. In accordance with various embodiments, the method further includes providing frequency compensation for a feedback loop of the current feedback amplifier using a gate capacitance of the n-type output transistor.

In some embodiments, the method further includes controlling a DC bias voltage of the input of the current feedback amplifier using a reference voltage. According to a number of embodiments, the method further includes using a digital-to-analog converter to generate the reference voltage based on a digital control signal. In accordance with several embodiments, the current feedback amplifier includes a p-type input transistor, an n-type input transistor, a first gate bias circuit configured to bias a gate of the p-type input transistor based on the reference voltage, and a second gate bias circuit configured to bias a gate of the n-type input transistor based on the reference voltage.

In various embodiments, a second feedback resistor is electrically connected between a second output of the current feedback amplifier and the input of the current feedback amplifier, one of the feedback resistor or the second feedback resistor selectively activated based on a band select signal.

In several embodiments, a driver amplifier has an input electrically connected to the input terminal and an input balun has a first winding electrically connected to an output of the driver amplifier and a second winding electrically connected between an input of the first amplifier and an input of the second amplifier.

In some embodiments, the method further includes a bias circuit to adjust a bias of at least one of the first amplifier or the second amplifier based on an output voltage of the envelope control amplifier.

### BRIEF DESCRIPTION OF THE DRAWINGS

FIG. 1 is a schematic diagram of one example of a communication network.

FIG. 2A is a schematic diagram of one example of a communication link using carrier aggregation.

FIG. 2B illustrates various examples of uplink carrier aggregation for the communication link of FIG. 2A.

FIG. 2C illustrates various examples of downlink carrier aggregation for the communication link of FIG. 2A.

FIG. 3A is a schematic diagram of one example of a downlink channel using multi-input and multi-output (MIMO) communications.

FIG. 3B is schematic diagram of one example of an uplink channel using MIMO communications.

FIG. 3C is schematic diagram of another example of an uplink channel using MIMO communications.

FIG. 4 is a schematic diagram of an example dual connectivity network topology.

FIG. 5 is a schematic diagram of a load modulated power amplifier according to one embodiment.

FIG. 6 is a schematic diagram of a radio frequency (RF) module according to one embodiment.

FIG. 7 is a schematic diagram of an envelope control amplifier die according to one embodiment.

FIG. 8A is a schematic diagram of an envelope control amplifier according to one embodiment.

FIG. 8B is a schematic diagram of an envelope control amplifier according to another embodiment.

FIG. 9 is a schematic diagram of one embodiment of an input transconductance stage for an envelope control amplifier.

FIG. 10 is a graph of one example of output voltage versus time for an envelope control amplifier with current feedback.

FIG. 11 is a schematic diagram of one embodiment of a mobile device.

### DETAILED DESCRIPTION OF EMBODIMENTS

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The International Telecommunication Union (ITU) is a specialized agency of the United Nations (UN) responsible for global issues concerning information and communication technologies, including the shared global use of radio spectrum.

The 3rd Generation Partnership Project (3GPP) is a collaboration between groups of telecommunications standard bodies across the world, such as the Association of Radio Industries and Businesses (ARIB), the Telecommunications Technology Committee (TTC), the China Communications Standards Association (CCSA), the Alliance for Telecommunications Industry Solutions (ATIS), the Telecommunications Technology Association (TTA), the European Telecommunications Standards Institute (ETSI), and the Telecommunications Standards Development Society, India (TSDSI).

Working within the scope of the ITU, 3GPP develops and maintains technical specifications for a variety of mobile communication technologies, including, for example, second generation (2G) technology (for instance, Global System for Mobile Communications (GSM) and Enhanced Data Rates for GSM Evolution (EDGE)), third generation (3G) technology (for instance, Universal Mobile Telecommunications System (UMTS) and High Speed Packet Access (HSPA)), and fourth generation (4G) technology (for instance, Long Term Evolution (LTE) and LTE-Advanced).

The technical specifications controlled by 3GPP can be expanded and revised by specification releases, which can span multiple years and specify a breadth of new features and evolutions.

In one example, 3GPP introduced carrier aggregation (CA) for LTE in Release 10. Although initially introduced with two downlink carriers, 3GPP expanded carrier aggregation in Release 14 to include up to five downlink carriers and up to three uplink carriers. Other examples of new features and evolutions provided by 3GPP releases include, but are not limited to, License Assisted Access (LAA), enhanced LAA (eLAA), Narrowband Internet of things (NB-IOT), Vehicle-to-Everything (V2X), and High Power User Equipment (HPUE).

3GPP introduced Phase 1 of fifth generation (5G) technology in Release 15 and introduced Phase 2 of 5G technology in Release 16. Subsequent 3GPP releases will further evolve and expand 5G technology. 5G technology is also referred to herein as 5G New Radio (NR).

5G NR supports or plans to support a variety of features, such as communications over millimeter wave spectrum, beamforming capability, high spectral efficiency waveforms, low latency communications, multiple radio numerology, and/or non-orthogonal multiple access (NOMA). Although such RF functionalities offer flexibility to networks and enhance user data rates, supporting such features can pose a number of technical challenges.

The teachings herein are applicable to a wide variety of communication systems, including, but not limited to, communication systems using advanced cellular technologies, such as LTE-Advanced, LTE-Advanced Pro, and/or 5G NR.

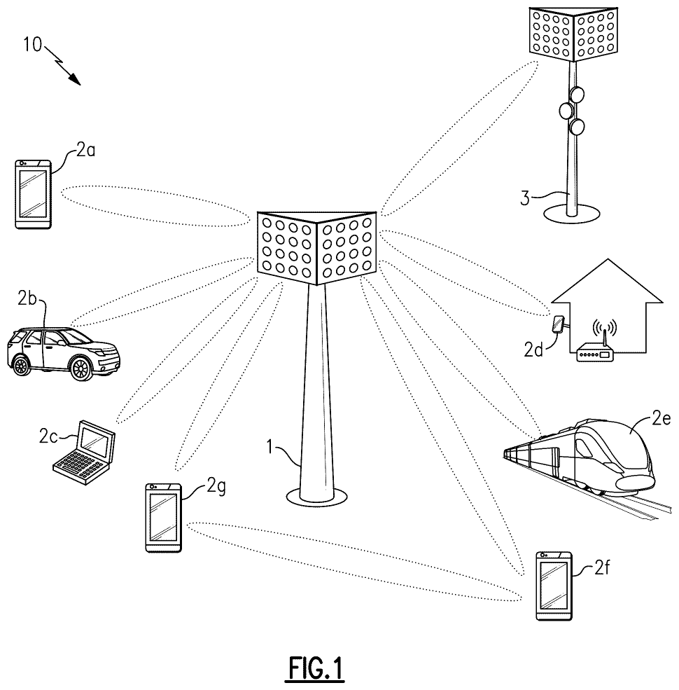

FIG. 1 is a schematic diagram of one example of a communication network 10. The communication network 10 includes a macro cell base station 1, a small cell base station 3, and various examples of user equipment (UE), including a first mobile device 2a, a wireless-connected car 2b, a laptop 2c, a stationary wireless device 2d, a wireless-connected train 2e, a second mobile device 2f, and a third mobile device 2g.

Although specific examples of base stations and user equipment are illustrated in FIG. 1, a communication network can include base stations and user equipment of a wide variety of types and/or numbers.

For instance, in the example shown, the communication network 10 includes the macro cell base station 1 and the small cell base station 3. The small cell base station 3 can operate with relatively lower power, shorter range, and/or with fewer concurrent users relative to the macro cell base station 1. The small cell base station 3 can also be referred to as a femtocell, a picocell, or a microcell. Although the communication network 10 is illustrated as including two base stations, the communication network 10 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 10 of FIG. 1 supports communications using a variety of cellular technologies, including, for example, 4G LTE and 5G NR. In certain implementations, the communication network 10 is further adapted to provide a wireless local area network (WLAN), such as WiFi. Although various examples of communication technologies have been provided, the communication network 10 can be adapted to support a wide variety of communication technologies.

Various communication links of the communication network 10 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 1, the communication links include not only communication links between UE and base stations, but also UE to UE communications and base station to base station communications. For example, the communication network 10 can be implemented to support self-fronthaul and/or self-backhaul (for instance, as between mobile device 2g and mobile device 2f).

The communication links can operate over a wide variety of frequencies. For example, the communication links can serve Frequency Range 1 (FR1), Frequency Range 2 (FR2), or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz. Cellular user equipment can communicate using beamforming and/or other techniques over a wide range of frequencies, including, for example, FR2-1 (24 GHz to 52 GHz), FR2-2 (52 GHz to 71 GHz), and/or FR1 (400 MHz to 7125 MHz).

Different users of the communication network 10 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refer to technology for communication with very low latency, for instance, less than 2 milliseconds. uRLLC can be used for mission-critical communications such as for autonomous driving and/or remote surgery applications. Massive machine-type communications (mMTC) refer to low cost and low data rate communications associated with wireless connections to everyday objects, such as those associated with Internet of Things (IoT) applications.

The communication network 10 of FIG. 1 can be used to support a wide variety of advanced communication features, including, but not limited to, eMBB, uRLLC, and/or mMTC.

In certain implementations, the communication network 10 supports supplementary uplink (SUL) and/or supplementary downlink (SDL). For example, when channel conditions are good, the communication network 10 can direct a particular UE to transmit using an original uplink frequency, while when channel condition is poor (for instance, below a certain criteria) the communication network 10 can direct the UE to transmit using a supplementary uplink frequency that is lower than the original uplink frequency. Since cell coverage increases with lower frequency, communication range and/or signal-to-noise ratio (SNR) can be increased using SUL. Likewise, SDL can be used to transmit using an original downlink frequency when channel conditions are good, and to transmit using a supplementary downlink frequency when channel conditions are poor.

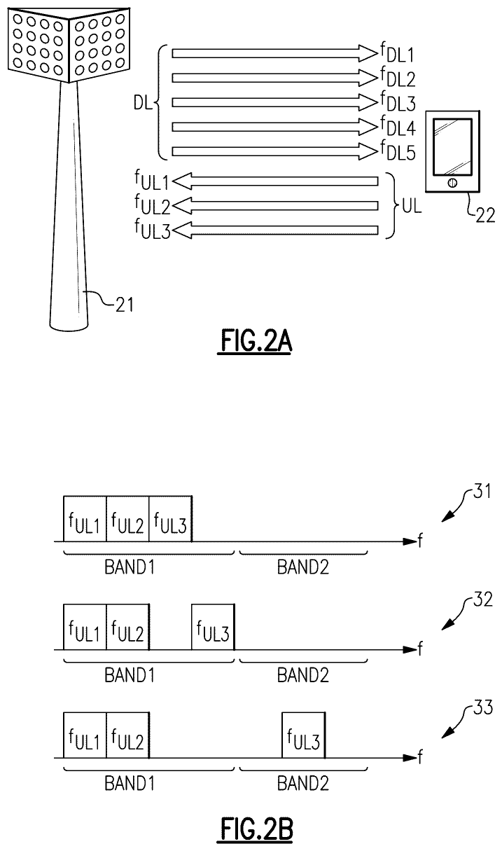

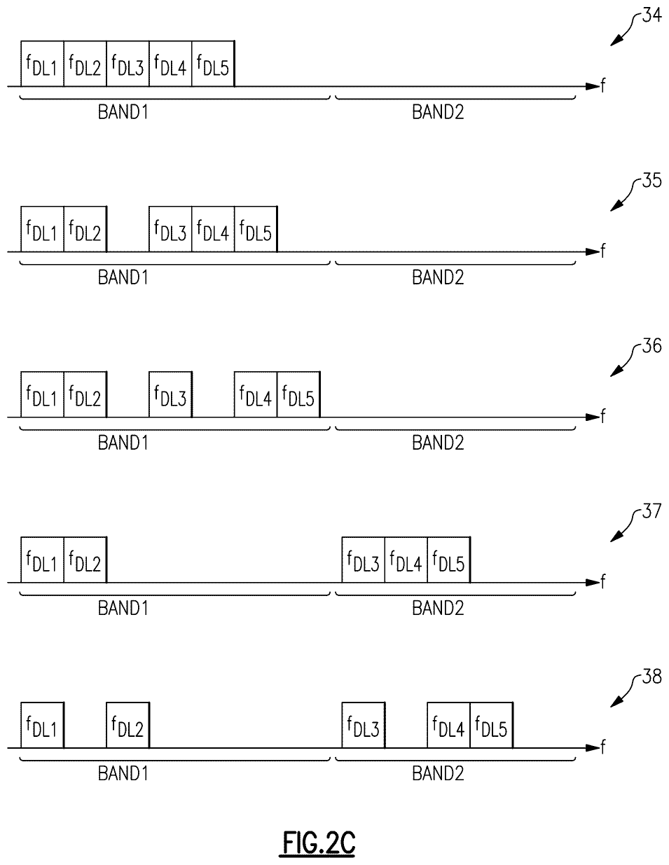

FIG. 2A is a schematic diagram of one example of a communication link using carrier aggregation. Carrier aggregation can be used to widen bandwidth of the communication link by supporting communications over multiple frequency carriers, thereby increasing user data rates and enhancing network capacity by utilizing fragmented spectrum allocations.

In the illustrated example, the communication link is provided between a base station 21 and a mobile device 22. As shown in FIG. 2A, the communications link includes a downlink channel used for RF communications from the base station 21 to the mobile device 22, and an uplink channel used for RF communications from the mobile device 22 to the base station 21.

Although FIG. 2A illustrates carrier aggregation in the context of FDD communications, carrier aggregation can also be used for TDD communications.

In certain implementations, a communication link can provide asymmetrical data rates for a downlink channel and an uplink channel. For example, a communication link can be used to support a relatively high downlink data rate to enable high speed streaming of multimedia content to a mobile device, while providing a relatively slower data rate for uploading data from the mobile device to the cloud.

In the illustrated example, the base station 21 and the mobile device 22 communicate via carrier aggregation, which can be used to selectively increase bandwidth of the communication link. Carrier aggregation includes contiguous aggregation, in which contiguous carriers within the same operating frequency band are aggregated. Carrier aggregation can also be non-contiguous and can include carriers separated in frequency within a common band or in different bands.

In the example shown in FIG. 2A, the uplink channel includes three aggregated component carriers f_{UL1}, f_{UL2}, and f_{UL3}. Additionally, the downlink channel includes five aggregated component carriers f_{DL1}, f_{DL2}, f_{DL3}, f_{DL4}, and f_{DL5}. Although one example of component carrier aggregation is shown, more or fewer carriers can be aggregated for uplink and/or downlink. Moreover, a number of aggregated carriers can be varied over time to achieve desired uplink and downlink data rates.

For example, a number of aggregated carriers for uplink and/or downlink communications with respect to a particular mobile device can change over time. For example, the number of aggregated carriers can change as the device moves through the communication network and/or as network usage changes over time.

FIG. 2B illustrates various examples of uplink carrier aggregation for the communication link of FIG. 2A. FIG. 2B includes a first carrier aggregation scenario 31, a second carrier aggregation scenario 32, and a third carrier aggregation scenario 33, which schematically depict three types of carrier aggregation.

The carrier aggregation scenarios 31-33 illustrate different spectrum allocations for a first component carrier f_{UL1}, a second component carrier f_{UL2}, and a third component carrier f_{UL3}. Although FIG. 2B is illustrated in the context of aggregating three component carriers, carrier aggregation can be used to aggregate more or fewer carriers. Moreover, although illustrated in the context of uplink, the aggregation scenarios are also applicable to downlink.

The first carrier aggregation scenario 31 illustrates intra-band contiguous carrier aggregation, in which component carriers that are adjacent in frequency and in a common frequency band are aggregated. For example, the first carrier aggregation scenario 31 depicts aggregation of component carriers f_{UL1}, f_{UL2}, and f_{UL3} that are contiguous and located within a first frequency band BAND1.

With continuing reference to FIG. 2B, the second carrier aggregation scenario 32 illustrates intra-band non-continuous carrier aggregation, in which two or more components carriers that are non-adjacent in frequency and within a common frequency band are aggregated. For example, the second carrier aggregation scenario 32 depicts aggregation of component carriers f_{UL1}, f_{UL2}, and f_{UL3} that are non-contiguous, but located within a first frequency band BAND1.

The third carrier aggregation scenario 33 illustrates inter-band non-contiguous carrier aggregation, in which component carriers that are non-adjacent in frequency and in multiple frequency bands are aggregated. For example, the third carrier aggregation scenario 33 depicts aggregation of component carriers f_{UL1} and f_{UL2} of a first frequency band BAND1 with component carrier f_{UL3} of a second frequency band BAND2.

FIG. 2C illustrates various examples of downlink carrier aggregation for the communication link of FIG. 2A. The examples depict various carrier aggregation scenarios 34-38 for different spectrum allocations of a first component carrier f_{DL1}, a second component carrier f_{DL2}, a third component carrier f_{DL3}, a fourth component carrier f_{DL4}, and a fifth component carrier f_{DL5}. Although FIG. 2C is illustrated in the context of aggregating five component carriers, carrier aggregation can be used to aggregate more or fewer carriers. Moreover, although illustrated in the context of downlink, the aggregation scenarios are also applicable to uplink.

The first carrier aggregation scenario 34 depicts aggregation of component carriers that are contiguous and located within the same frequency band. Additionally, the second carrier aggregation scenario 35 and the third carrier aggregation scenario 36 illustrates two examples of aggregation that are non-contiguous but located within the same frequency band. Furthermore, the fourth carrier aggregation scenario 37 and the fifth carrier aggregation scenario 38 illustrates two examples of aggregation in which component carriers that are non-adjacent in frequency and in multiple frequency bands are aggregated. As a number of aggregated component carriers increases, the complexity of possible carrier aggregation scenarios also increases.

With reference to FIGS. 2A-2C, the individual component carriers used in carrier aggregation can be of a variety of frequencies, including, for example, frequency carriers in the same band or in multiple bands. Additionally, carrier aggregation is applicable to implementations in which the individual component carriers are of about the same bandwidth as well as to implementations in which the individual component carriers have different bandwidths.

Certain communication networks allocate a particular user device with a primary component carrier (PCC) or anchor carrier for uplink and a PCC for downlink. Additionally, when the mobile device communicates using a single frequency carrier for uplink or downlink, the user device communicates using the PCC. To enhance bandwidth for uplink communications, the uplink PCC can be aggregated with one or more uplink secondary component carriers (SCCs). Additionally, to enhance bandwidth for downlink communications, the downlink PCC can be aggregated with one or more downlink SCCs.

In certain implementations, a communication network provides a network cell for each component carrier. Additionally, a primary cell can operate using a PCC, while a secondary cell can operate using a SCC. The primary and secondary cells may have different coverage areas, for instance, due to differences in frequencies of carriers and/or network environment.

License assisted access (LAA) refers to downlink carrier aggregation in which a licensed frequency carrier associated with a mobile operator is aggregated with a frequency carrier in unlicensed spectrum, such as WiFi. LAA employs a downlink PCC in the licensed spectrum that carries control and signaling information associated with the communication link, while unlicensed spectrum is aggregated for wider downlink bandwidth when available. LAA can operate with dynamic adjustment of secondary carriers to avoid WiFi users and/or to coexist with WiFi users. Enhanced license assisted access (eLAA) refers to an evolution of LAA that aggregates licensed and unlicensed spectrum for both downlink and uplink. Furthermore, NR-U can operate on top of LAA/eLAA over a 5 GHz band (5150 to 5925 MHz) and/or a 6 GHz band (5925 MHz to 7125MHz).

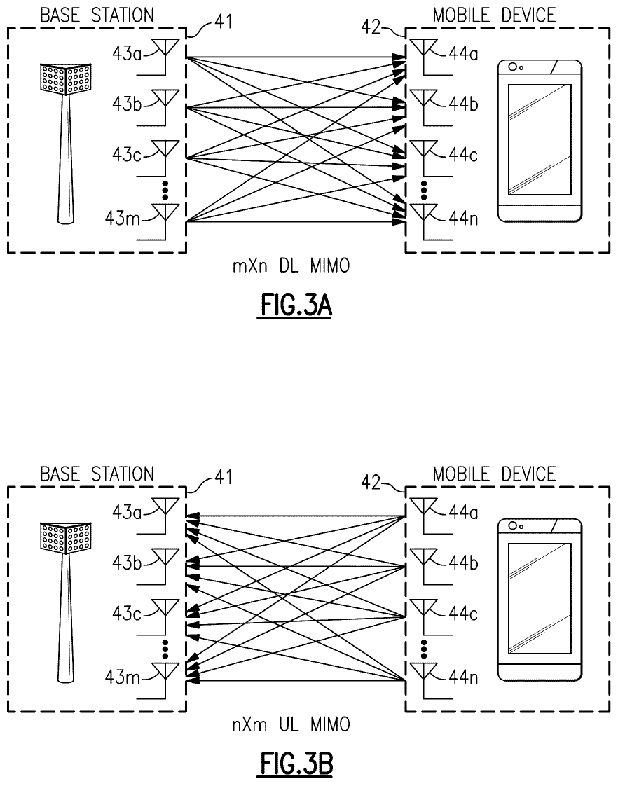

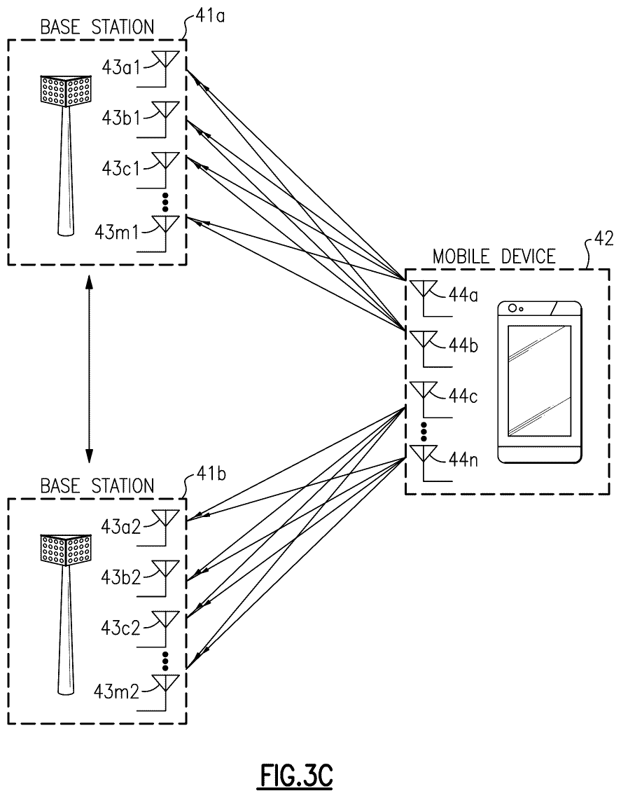

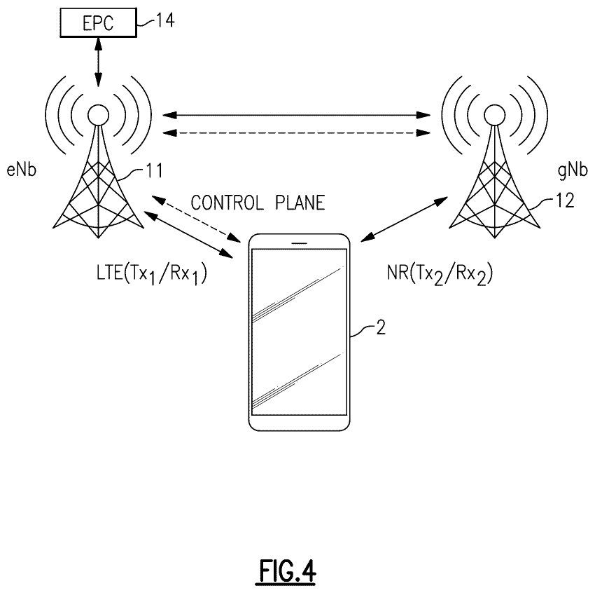

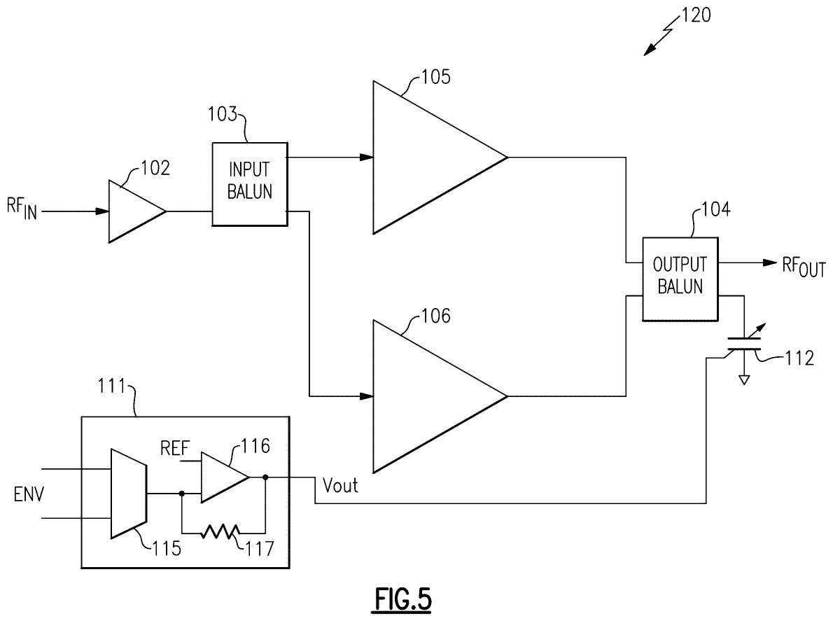

FIG. 3A is a schematic diagram of one example of a downlink channel using multi-input and multi-output (MIMO) communications. FIG. 3B is schematic diagram of one example of an uplink channel using MIMO communications.

MIMO communications use multiple antennas for simultaneously communicating multiple data streams over common frequency spectrum. In certain implementations, the data streams operate with different reference signals to enhance data reception at the receiver. MIMO communications benefit from higher SNR, improved coding, and/or reduced signal interference due to spatial multiplexing differences of the radio environment.

MIMO order refers to a number of separate data streams sent or received. For instance, MIMO order for downlink communications can be described by a number of transmit antennas of a base station and a number of receive antennas for UE, such as a mobile device. For example, two-by-two (2×2) DL MIMO refers to MIMO downlink communications using two base station antennas and two UE antennas. Additionally, four-by-four (4×4) DL MIMO refers to MIMO downlink communications using four base station antennas and four UE antennas.

In the example shown in FIG. 3A, downlink MIMO communications are provided by transmitting using M antennas 43a, 43b, 43c, . . . 43m of the base station 41 and receiving using N antennas 44a, 44b, 44c, . . . 44n of the mobile device 42. Accordingly, FIG. 3A illustrates an example of m×n DL MIMO.

Likewise, MIMO order for uplink communications can be described by a number of transmit antennas of UE, such as a mobile device, and a number of receive antennas of a base station. For example, 2×2 UL MIMO refers to MIMO uplink communications using two UE antennas and two base station antennas. Additionally, 4×4 UL MIMO refers to MIMO uplink communications using four UE antennas and four base station antennas.

In the example shown in FIG. 3B, uplink MIMO communications are provided by transmitting using N antennas 44a, 44b, 44c, . . . 44n of the mobile device 42 and receiving using M antennas 43a, 43b, 43c, . . . 43m of the base station 41. Accordingly, FIG. 3B illustrates an example of n×m UL MIMO.

By increasing the level or order of MIMO, bandwidth of an uplink channel and/or a downlink channel can be increased.

MIMO communications are applicable to communication links of a variety of types, such as FDD communication links and TDD communication links.

FIG. 3C is schematic diagram of another example of an uplink channel using MIMO communications. In the example shown in FIG. 3C, uplink MIMO communications are provided by transmitting using N antennas 44a, 44b, 44c, . . . 44n of the mobile device 42. Additional a first portion of the uplink transmissions are received using M antennas 43a1, 43b1, 43c1, . . . 43m1 of a first base station 41a, while a second portion of the uplink transmissions are received using M antennas 43a2, 43b2, 43c2, . . . 43m2 of a second base station 41b. Additionally, the first base station 41a and the second base station 41b communication with one another over wired, optical, and/or wireless links.

The MIMO scenario of FIG. 3C illustrates an example in which multiple base stations cooperate to facilitate MIMO communications.

With the introduction of the 5G NR air interface standards, 3GPP has allowed for the simultaneous operation of 5G and 4G standards in order to facilitate the transition. This mode can be referred to as Non-Stand-Alone (NSA) operation or E-UTRAN New Radio-Dual Connectivity (EN-DC) and involves both 4G and 5G carriers being simultaneously transmitted from a user equipment (UE).

In certain EN-DC applications, dual connectivity NSA involves overlaying 5G systems onto an existing 4G core network. For dual connectivity in such applications, the control and synchronization between the base station and the UE can be performed by the 4G network while the 5G network is a complementary radio access network tethered to the 4G anchor. The 4G anchor can connect to the existing 4G network with the overlay of 5G data/control.

FIG. 4 is a schematic diagram of an example dual connectivity network topology. This architecture can leverage LTE legacy coverage to ensure continuity of service delivery and the progressive rollout of 5G cells. A UE 2 can simultaneously transmit dual uplink LTE and NR carrier. The UE 2 can transmit an uplink LTE carrier Tx1 to the eNB 11 while transmitting an uplink NR carrier Tx2 to the gNB 12 to implement dual connectivity. Any suitable combination of uplink carriers Tx1, Tx2 and/or downlink carriers Rx1, Rx2 can be concurrently transmitted via wireless links in the example network topology of FIG. 1. The eNB 11 can provide a connection with a core network, such as an Evolved Packet Core (EPC) 14. The gNB 12 can communicate with the core network via the eNB 11. Control plane data can be wireless communicated between the UE 2 and eNB 11. The eNB 11 can also communicate control plane data with the gNB 12. Control plane data can propagate along the paths of the dashed lines in FIG. 4. The solid lines in FIG. 4 are for data plane paths.

In the example dual connectivity topology of FIG. 4, any suitable combinations of standardized bands and radio access technologies (e.g., FDD, TDD, SUL, SDL) can be wirelessly transmitted and received. This can present technical challenges related to having multiple separate radios and bands functioning in the UE 2. With a TDD LTE anchor point, network operation may be synchronous, in which case the operating modes can be constrained to Tx1/Tx2 and Rx1/Rx2, or asynchronous which can involve Tx1/Tx2, Tx1/Rx2, Rx1/Tx2, Rx1/Rx2. When the LTE anchor is a frequency division duplex (FDD) carrier, the TDD/FDD inter-band operation can involve simultaneous Tx1/Rx1/Tx2 and Tx1/Rx1/Rx2.

### Examples of Current Feedback Amplifiers for Load Modulated Envelope Tracking

A load modulated power amplifier can include a pair of amplifiers and an output balun that includes a primary winding or coil electrically connected between the outputs of the pair of amplifiers. Additionally, the secondary winding of the output balun can be electrically connected between an RF output terminal and a load modulation capacitor. The load modulated power amplifier amplifies an RF signal, and the capacitance value of the load modulation capacitor can be dynamically controlled using an envelope control amplifier to provide load modulation.

Thus, a load modulated power amplifier can operate based on dynamically varying a load modulation capacitor connected at the secondary coil of the output balun as a function of an envelope of an RF signal. By dynamically varying the capacitance value in this manner, the differential output impedance seen by the pair of amplifiers changes according to the envelope. For saturated power levels, the impedance of the power amplifier's load line is sufficiently low to deliver saturated output power, while for backed-off power levels the load line impedance increases so that the power amplifier still operates efficiently at reduced power.

To achieve the benefits of load modulation, the envelope control amplifier should properly change the capacitance value of the load modulation capacitor in accordance with the envelope to provide the correct amount of load modulation.

However, implementing an envelope control amplifier for a load modulated power amplifier can be difficult. For example, the envelope control amplifier can be specified to support 100 MHz or more bandwidth for the envelope signal, to provide a differential to single-ended conversion, high common-mode rejection ratio (CMRR), and/or a slew rate of 400 V/μs or higher. Such specifications can be particularly difficult to implement on silicon processes, such as bulk complementary metal oxide semiconductor (CMOS) processes.

Current feedback amplifiers for load modulated envelope tracking are disclosed. In certain embodiments, a load modulated power amplifier for amplifying an RF signal includes a controllable capacitor for adjusting the power amplifier's load impedance and an envelope control amplifier for controlling a capacitance value of the controllable capacitor based on an envelope signal indicating an envelope of the RF signal. The envelope control amplifier includes an input transconductance stage that receives the envelope signal, a current feedback amplifier having an input electrically connected to an output of the input transconductance stage and an output that controls the controllable capacitor, and a feedback resistor electrically connected between the output of the current feedback amplifier and the input of the current feedback amplifier.

Accordingly, the envelope control amplifier includes a current feedback amplifier. Using a current feedback amplifier can provide low input impedance, reduced input parasitics, fast slew rates, and/or enhanced stability.

In contrast, voltage feedback amplifiers may be unable to deliver suitable bandwidth and/or slew rate for load modulation. Furthermore, voltage feedback amplifiers may suffer from instability due to a pole arising from the amplifier's high input parasitic capacitance.

FIG. 5 is a schematic diagram of a load modulated power amplifier 120 according to one embodiment. The load modulated power amplifier 120 includes a driver amplifier 102, an input balun 103, an output balun 104, a first amplifier 105, a second amplifier 106 (the first amplifier 105 and the second amplifier 106 are collectively referred to herein as a pair of amplifiers), an envelope control amplifier 111, and a controllable load modulation capacitor 112.

As shown in FIG. 5, the load modulated power amplifier 120 includes an input terminal that receives an RF input signal RF_{IN} and an output terminal that outputs an RF output signal RF_{OUT} corresponding to an amplified version of the RF input signal RF_{IN}.

In the illustrated embodiment, the driver amplifier 102 includes an input electrically connected to the input terminal and an output electrically connected to a primary winding of the input balun 103. Additionally, a secondary winding of the input balun 103 is electrically connected between an input of the first amplifier 105 and an input of the second amplifier 106. Furthermore, a primary winding of the output balun 104 is electrically connected between an output of the first amplifier 105 and an output of the second amplifier 106. The input balun 103, the pair of amplifiers 105/106, and the output balun 104 are arranged in a push-pull configuration, in this embodiment.

As shown in FIG. 5, a secondary winding of the output balun 104 is electrically connected between the output terminal and a first end of the load modulation capacitor 112. Additionally, a second end of the load modulation capacitor 112 is electrically connected to a reference voltage (corresponding to a ground voltage or ground, in this example).

With continuing reference to FIG. 5, the envelope control amplifier 111 controls the capacitance value of the load modulation capacitor 112 based on an envelope signal ENV indicating an envelope of the RF input signal RF_{IN}. Thus, the capacitance value of the load modulation capacitor 112 is dynamically controlled by the envelope control amplifier 111 to provide load modulation.

In the illustrated embodiment, the envelope control amplifier 111 includes an input transconductance stage 115 that receives the envelope signal ENV (which can be single-ended or differential) and a current feedback amplifier 116 having an input electrically connected to an output of the input transconductance stage 115, a reference input that receives a reference voltage REF, and an output that generates an output voltage Vout that controls a capacitance value of the load modulation capacitor 112. The envelope control amplifier 111 further includes a feedback resistor 117 electrically connected between the output of the current feedback amplifier 116 and the input of the current feedback amplifier 116.

Including the current feedback amplifier 116 in the envelope control amplifier 111 can provide several advantages such as providing low input impedance, reduced input parasitics, and/or enhanced stability. Furthermore, implementing the envelope control amplifier 111 in this manner can provide high common-mode rejection ratio (CMRR), wide bandwidth, and/or high slew rate.

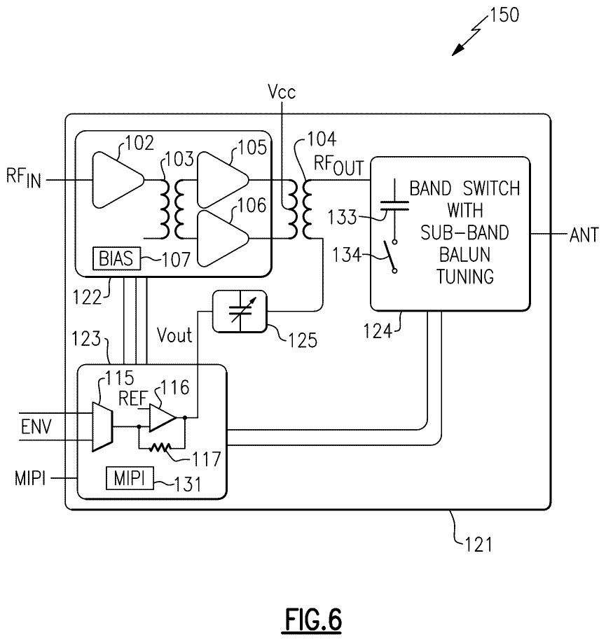

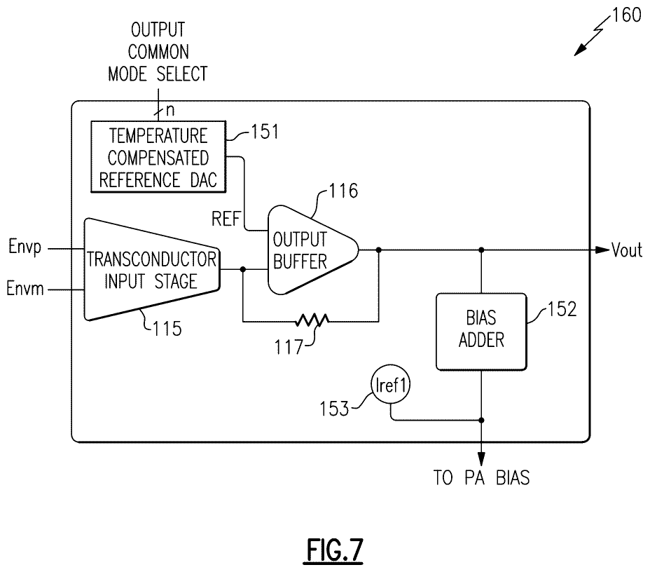

FIG. 6 is a schematic diagram of an RF module 150 according to one embodiment. The RF module 150 includes a module substrate 121 (for instance, a circuit board), an output balun 104, a power amplifier die 122, an envelope control amplifier die 123, a switch die 124, and a load modulation capacitor 125.

Various inputs and outputs of the RF module 150 are depicted, including an RF input terminal for receiving an RF input signal RF_{IN}, a power supply voltage terminal for receiving a power supply voltage Vcc (provided to a center tap of the primary winding of the output balun 104, in this example), an envelope terminal for receiving an envelope signal ENV, a control bus (mobile industry processor interface or MIPI, in this example) and an antenna terminal ANT for connecting to an antenna.

The RF module 150 depicts an example implementation of a load modulated power amplifier on a multi-chip module (MCM). However, the load modulated power amplifiers herein can be implemented in other ways.

In the illustrated embodiment, the power amplifier die 122 is attached to the module substrate 121 and includes a driver amplifier 102, an input balun 103, a first amplifier 105, a second amplifier 106, and a bias circuit 107. The depicted on-chip components of the load modulated power amplifier operate in combination with the output balun 104 to provide a push-pull power amplifier that amplifies the RF input signal RF_{IN} to generate an RF output signal RF_{OUT}. The power amplifier die 122 also includes the bias circuit 107 for biasing the driver amplifier 102, the first amplifier 105, and/or the second amplifier 106. The power amplifier die 122 receives one or more control signals from the envelope control amplifier die 123, such as control signals generated based on data received over the MIPI bus. In certain implementations, the control signals include a bias adjustment signal for dynamically adjusting the bias signal(s) outputted from the bias circuit 107 based on an output voltage Vout for controlling the load modulation capacitor 125.

As shown in FIG. 6, the RF output signal RF_{OUT} is provided to the switch die 124, which is attached to the module substrate 121 and includes a band switch implemented with sub-band tuning (for instance, using a capacitor 133 and a switch 134 for tuning). The band switch receives one or more control signals from the envelope control amplifier die 123, such as control signals generated based on data received over the MIPI bus. The band switch is coupled to the antenna terminal ANT, which connects to an antenna.

With continuing reference to FIG. 6, the envelope control amplifier die 123 includes a bus interface circuit 131 coupled to the MIPI bus, an input transconductance stage 115 that receives the envelope signal ENV, and a current feedback amplifier 116 having an input electrically connected to an output of the input transconductance stage 115, a reference input that receives a reference voltage REF, and an output that generates the output voltage Vout for controlling the load modulation capacitor 125. In this example, the load modulation capacitor 125 is implemented as a component attached to the module substrate 121 using surface-mount technology (SMT). The load modulation capacitor 125 is coupled to a secondary winding of the output balun 104, which in some configurations can be implemented by patterning one or more layers of the module substrate 121. The envelope control amplifier die 123 further includes a feedback resistor 117 electrically connected between the output of the current feedback amplifier 116 and the input of the current feedback amplifier 116.

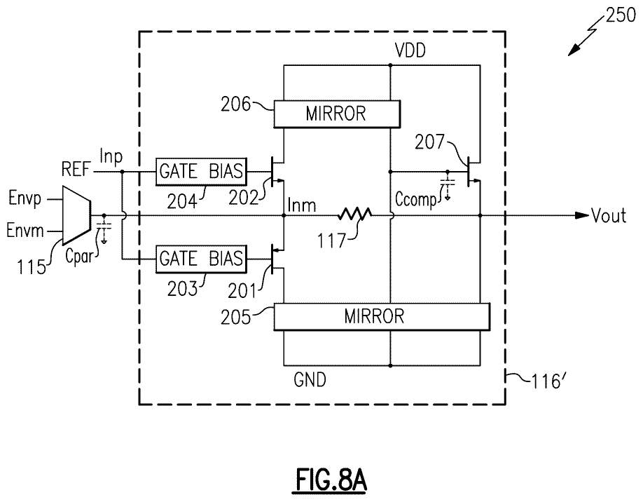

FIG. 7 is a schematic diagram of an envelope control amplifier die 160 according to one embodiment. The envelope control amplifier die 160 includes a temperature compensated reference digital-to-analog converter (DAC) 151, an input transconductance stage 115, a current feedback amplifier 116, a feedback resistor 117, a bias adder 152, and a reference current source 153.

The envelope control amplifier die 160 depicts another example of a semiconductor die that can include a load modulated power amplifier. However, the load modulated power amplifiers herein can be implemented in other ways.

In the illustrated embodiment, the input transconductance stage 115 includes a differential input that receives an envelope signal including a positive or non-inverted signal component Envp and a negative or inverted signal component Envm. The current feedback amplifier 116 has an input electrically connected to an output of the input transconductance stage 115, a reference input that receives a reference voltage REF from the temperature compensated reference DAC 151, and an output that generates an output voltage Vout for controlling a load modulation capacitor (not shown in FIG. 6). The feedback resistor 117 is electrically connected between the output of the current feedback amplifier 116 and the input of the current feedback amplifier 116. The current feedback amplifier 116 operates as an output buffer, in this example.

As shown in FIG. 7, the temperature compensated reference DAC receives an n-bit control signal for controlling an input common-mode voltage of the current feedback amplifier 116, where n can be any desired number of bits. In certain implementations, the n-bit control signal provides trimming to account for part-to-part variation in input common-mode voltage of the current feedback amplifier 116 arising from process variation. By providing trimming in this manner, process variation can be accounted for and the input common-mode voltage of the current feedback amplifier 116 can be relatively consistent from part to part.

In the illustrated embodiment, the bias adder 152 is used to provide an adjustment to a reference current Iref1 from the reference current source 153. The current adjustment is based on the output voltage Vout for controlling the load modulation capacitor. The adjusted reference current is provided to a power amplifier bias circuit (for example, the bias circuit 107 of FIG. 6), thus allowing the gain of the power amplifier to change as a function of the load modulation. For example, when the output voltage Vout is high, the power amplifier gain can be increased by the bias adjustment.

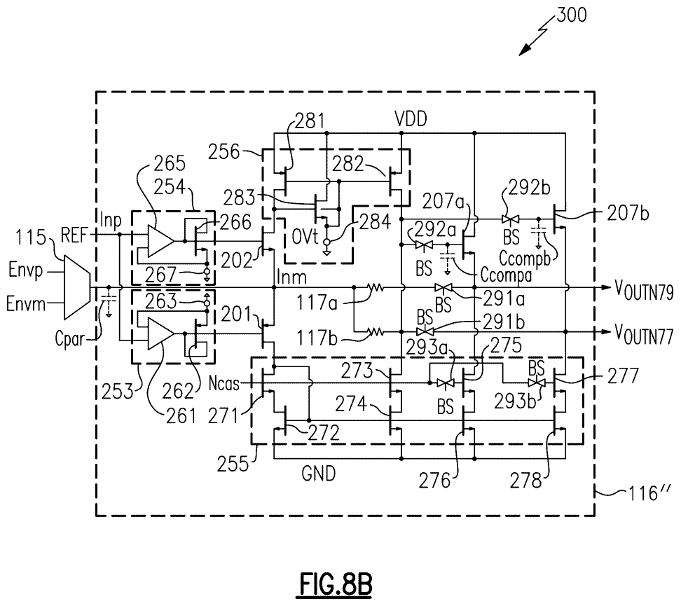

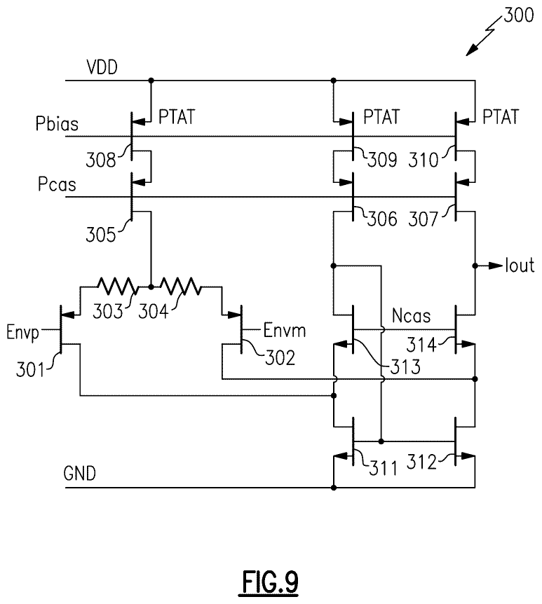

FIG. 8A is a schematic diagram of an envelope control amplifier 250 according to one embodiment. The envelope control amplifier 250 includes an input transconductance stage 115, a current feedback amplifier 116′, and a feedback resistor 117.

Although the envelope control amplifier 250 depicts one example of an envelope control amplifier, envelope control amplifiers can be implemented in other ways. Accordingly, other implementations are possible.

In the illustrated embodiment, the input transconductance stage 115 includes a differential voltage input that receives a differential envelope voltage including a non-inverted signal component Envp and an inverted signal component Envm. The input transconductance stage 115 further includes a current output that provides an output current to a current input Inm of the current feedback amplifier 116′. The feedback resistor 117 is electrically connected between a voltage output Vout of the current feedback amplifier 116′ and the current input Inm. A reference input Inp of the current feedback amplifier 116′ receives a reference voltage REF.

As shown in FIG. 8A, the current feedback amplifier 116′ includes a first gate bias circuit 203, a second gate bias circuit 204, an input p-type metal-oxide-semiconductor (PMOS) transistor 201, an input n-type metal-oxide-semiconductor (NMOS) transistor 202, a first current mirror 205, a second current mirror 206, and an output NMOS transistor 207.

In the illustrated embodiment, the first gate bias circuit 203 and the second gate bias circuit 204 control a gate bias voltage of the input PMOS transistor 201 and the input NMOS transistor 202, respectively, based on the reference voltage REF to thereby control a DC bias voltage at the current input Inm. Thus, the reference voltage REF can set the DC bias voltage of the current feedback amplifier 116′ to a desired bias voltage level.

The source of the input PMOS transistor 201 and the source of the input NMOS transistor 202 are each connected to the current input Inm. Thus, rather than having transistor gates directly connected to the current input Inm, transistors sources are directly connected to the current input Inm. Implementing the current feedback amplifier 116′ in this manner provides low input impedance at the current input Inm and results in a low parasitic capacitor Cpar, which aids in providing enhanced loop stability.

With continuing reference to FIG. 8A, a drain of the input PMOS transistor 201 is electrically connected to an input of the first current mirror 205, while a drain of the input NMOS transistor 202 is electrically connected to an input of the second current mirror 206. The first current mirror 205 is referenced to a ground voltage GND and includes a first output electrically connected to a gate of the output NMOS transistor 207 and a second output electrically connected to a source of the output NMOS transistor 207 at the voltage output Vout. The second current mirror 206 is reference to a power supply voltage VDD and includes an output electrically connected to the gate of the output NMOS transistor 207. The drain of the output NMOS transistor 207 is electrically connected to the power supply voltage VDD.

The input transconductance stage 115 amplifies the differential envelope voltage to generate an envelope current that is provided to the current input Inm of the current feedback amplifier 116′. The input transconductance stage 115 provides a differential to single-ended conversion while also providing a high CMRR.

The current feedback amplifier 116′ operates as a transimpedance amplifier. Based on a polarity of the envelope current and other operating conditions, the envelope current can flow through the input PMOS transistor 201 to the first current mirror 205 or through the input NMOS transistor 202 to the second current mirror 206. Additionally, the envelope current is mirrored and provided to the gate of the output NMOS transistor 207, which adjusts the output voltage Vout accordingly. The change in the output voltage Vout leads to a flow of current through the feedback resistor 117 to cancel the envelope current from the input transconductance stage 115. Thus, current feedback is provided.

In the illustrated embodiment, a gate capacitance of the output NMOS transistor 207 serves as a frequency compensation capacitor Ccomp for loop stability.

The envelope control amplifier 250 includes the current feedback amplifier 116′ to provide low input impedance, reduced input parasitics, and/or enhanced stability. Implementing the envelope control amplifier 250 in this manner also provide high CMRR, wide bandwidth, and/or high slew rate.

FIG. 8B is a schematic diagram of an envelope control amplifier 300 according to another embodiment. The envelope control amplifier 300 includes an input transconductance stage 115, a current feedback amplifier 116″, a first feedback resistor 117a, and a second feedback resistor 117b.

In the illustrated embodiment, the input transconductance stage 115 includes a differential voltage input that receives a differential envelope voltage including a non-inverted signal component Envp and an inverted signal component Envm. The input transconductance stage 115 further includes a current output that provides an output current to a current input Inm of the current feedback amplifier 116″. A reference input Inp of the current feedback amplifier 116″ receives a reference voltage REF.

As shown in FIG. 8B, the current feedback amplifier 116″ includes a first gate bias circuit 253, a second gate bias circuit 254, an input PMOS transistor 201, an input NMOS transistor 202, a first current mirror 255, a second current mirror 256, first output NMOS transistor 207a, a second output NMOS transistor 207b, a first output transmission gate 291a, a second output transmission gate 291b, a third output transmission gate 292a, a fourth output transmission gate 292b, a first current mirror transmission gate 293a, and a second current mirror transmission gate 293b.

The current feedback amplifier 116″ of FIG. 8B is similar to the current feedback amplifier 116′ of FIG. 8A, except that the current feedback amplifier 116″ of FIG. 8B depicts specific implementations of certain circuits and is also implemented with separately selectable voltage outputs for different frequency bands (corresponding to band n79 and band n77, in this embodiment) based on a band select signal BS.

For example, the band select signal BS can turn on the transmission gates 291a/292a/293a and turn off the transmission gates 291b/292b/293b in a first mode (band n79, in this example) to activate the first output NMOS transistor 207a and electrically connect the first feedback resistor 117a between a first voltage output V_{OUTN79} of the current feedback amplifier 116″ and the current input Inm. Additionally, the band select signal BS can turn off the transmission gates 291a/292a/293a and turn on the transmission gates 291b/292b/293b in a second mode (band n77, in this example) to activate the second output NMOS transistor 207b and electrically connect the second feedback resistor 117b between a second voltage output V_{OUTN77} of the current feedback amplifier 116″ and the current input Inm. Thus, the current feedback amplifier 116″ includes the first voltage output V_{OUTN79} for use in the band n79 mode and the second voltage output V_{OUTN77} for use in the band n77 mode.

In certain implementations, a gate capacitance of the first output NMOS transistor 207a serves as a first frequency compensation capacitor Ccompa in the band n79 mode, while a gate capacitance of the second output NMOS transistor 207b serves as a second frequency compensation capacitor Compb in the band n77 mode.

With continuing reference to FIG. 8B, the first gate bias circuit 253 includes a first error amplifier 261, a reference PMOS transistor 262, and a first reference current source 263, while the second gate bias circuit 254 includes a second error amplifier 265, a reference NMOS transistor 266, and a second reference current source 267. Additionally, the first error amplifier 261 controls a gate voltage of the reference PMOS transistor 262 by feedback to control the source of the reference PMOS transistor 262 to be about equal to the reference voltage REF. Furthermore, the second error amplifier 265 controls a gate voltage of the reference NMOS transistor 266 by feedback to control the source of the reference NMOS transistor 266 to be about equal to the reference voltage REF. Accordingly, the DC bias voltage level of the current input Inm is controlled to be about equal to the reference voltage REF since the gate voltage of the reference NMOS transistor 266 is provided to the input NMOS transistor 202 and the gate voltage of the reference PMOS transistor 262 is provided to the input PMOS transistor 201.

As shown in FIG. 8B, the first current mirror 255 includes an input cascode NMOS transistor 271, an input mirror NMOS transistor 272, a first output cascode NMOS transistor 273, a first output mirror NMOS transistor 274, a second output cascode NMOS transistor 275, a second output mirror NMOS transistor 276, a third output cascode NMOS transistor 277, a third output mirror NMOS transistor 278, the first current mirror transmission gate 293a, and the second current mirror transmission gate 293b. The depicted cascode NMOS transistors are biased by a cascode bias voltage Ncas.

In the illustrated embodiment, the second current mirror 256 includes an input mirror PMOS transistor 281 (corresponding to an enhancement mode or E-mode transistor), an output mirror PMOS transistor 282 (also corresponding to an E-mode transistor), a depletion mode (D-mode) NMOS transistor 283, and a reference current source 284. The D-mode NMOS transistor 283 can be implemented using a triple well isolation in a bulk CMOS process. The D-mode NMOS transistor 283 can also be referred to as a native or 0Vt device.

As shown in FIG. 8B, the D-mode NMOS transistor 283 includes a gate electrically connected to a drain of the input mirror PMOS transistor 281, a source and body electrically connected to the reference current source 284 and the gates of the input mirror PMOS transistor 281/output mirror PMOS transistor 282, and a drain electrically connected to a power supply voltage VDD.

The envelope control amplifier 300 includes the current feedback amplifier 116″ to provide low input impedance, reduced input parasitics, and/or enhanced stability. The envelope control amplifier 300 also provide high CMRR, wide bandwidth, and/or high slew rate. Furthermore, by including the D-mode NMOS transistor 283 in the second current mirror 256, improved voltage headroom can be achieved.

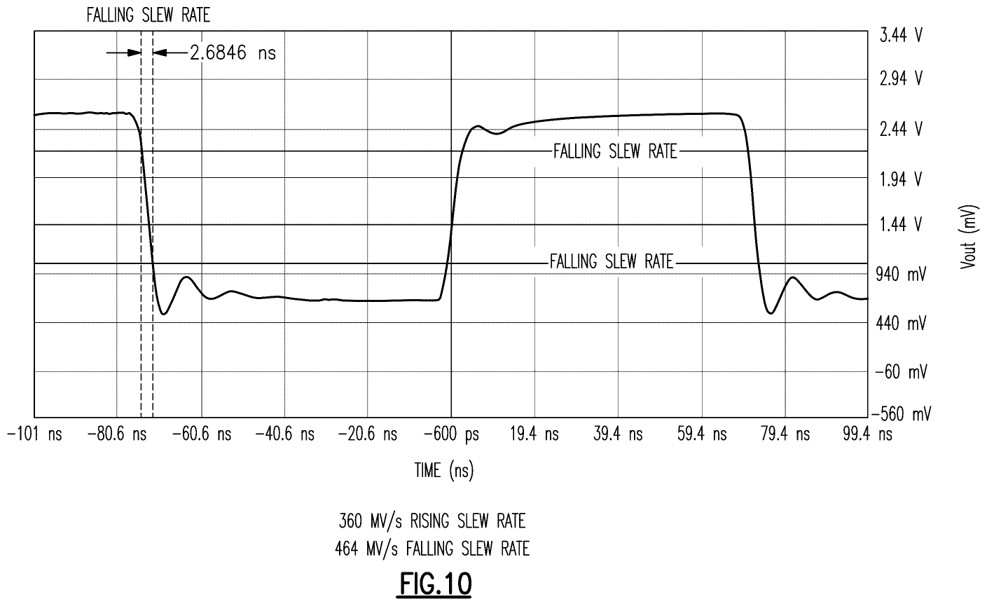

FIG. 9 is a schematic diagram of one embodiment of an input transconductance stage 300 for an envelope control amplifier. The input transconductance stage 300 includes a first input PMOS transistor 301, a second input PMOS transistor 302, a first resistor 303, a second resistor 304, a first cascode PMOS transistor 305, a second cascode PMOS transistor 306, a third cascode PMOS transistor 307, a first proportional to absolute temperature (PTAT) PMOS transistor 308, a second PTAT PMOS transistor 309, a third PTAT PMOS transistor 310, a first load NMOS transistor 311, a second load NMOS transistor 312, a first folded-cascode NMOS transistor 313, and a second folded-cascode NMOS transistor 314. The input transconductance stage 300 receives power by way of connections to a power supply voltage VDD and ground GND.

Although the input transconductance stage 300 depicts one example of an input transconductance stage for an envelope control amplifier, an input transconductance stage can be implemented in other ways. Accordingly, other implementations are possible.

As shown in FIG. 9, a first cascode bias voltage Pcas biases the gates of the cascode PMOS transistors 305-307 while a second cascode bias voltage Ncas biases the gates of the folded-cascode NMOS transistors 313/314. Additionally, a bias voltage Pbias biases the PTAT PMOS transistors 308-310 to operate as PTAT current sources.

In the illustrated embodiment, the first input PMOS transistor 301 receives the non-inverted signal component Envp of the envelope signal while the second input PMOS transistor 302 receives the inverted signal component Envn of the envelope signal. Additionally, a source of the first input PMOS transistor 301 is connected to a tail node through the first resistor 303, while a source of the second input PMOS transistor 302 is connected to the tail node through the second resistor 304. The transconductance of the input PMOS transistors 301-302 leads to a flow of current through the resistors 303-304, which leads to a change in output current at the current output Iout.

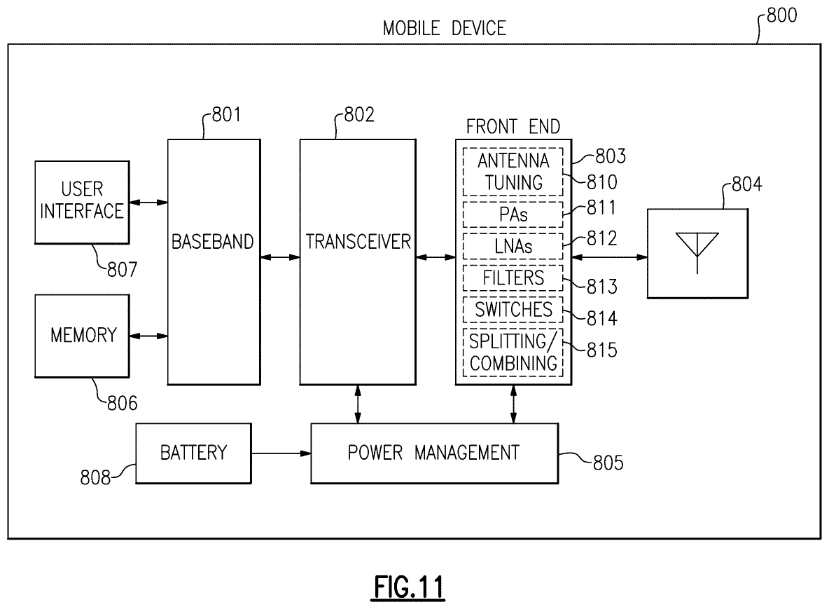

FIG. 10 is a graph of one example of output voltage versus time for an envelope control amplifier with current feedback. In this example, the envelope control amplifier exhibits a fast rising slew rate of 360 MV/s and a fast falling slew rate of 464 MV/s. However, other slew rates can be achieved based on implementation of the envelope control amplifier.

FIG. 11 is a schematic diagram of one embodiment of a mobile device 800. The mobile device 800 includes a baseband system 801, a transceiver 802, a front-end system 803, antennas 804, a power management system 805, a memory 806, a user interface 807, and a battery 808.

The mobile device 800 can be used communicate using a wide variety of communications technologies, including, but not limited to, 2G, 3G, 4G (including LTE, LTE-Advanced, and LTE-Advanced Pro), 5G NR, WLAN (for instance, WiFi), WPAN (for instance, Bluetooth and ZigBee), WMAN (for instance, WiMax), and/or GPS technologies.

The transceiver 802 generates RF signals for transmission and processes incoming RF signals received from the antennas 804. In transceiver 802 can also generate other signals, such as an envelope signal indicating the envelope of an RF signal to be transmitted. A transceiver is also referred to herein as a radio frequency integrated circuit (RFIC).

It will be understood that various functionalities associated with the transmission and receiving of RF signals can be achieved by one or more components that are collectively represented in FIG. 11 as the transceiver 802. In one example, separate components (for instance, separate circuits or dies) can be provided for handling certain types of RF signals.

The front-end system 803 aids in conditioning signals transmitted to and/or received from the antennas 804. In the illustrated embodiment, the front-end system 803 includes antenna tuning circuitry 810, power amplifiers (PAs) 811, low noise amplifiers (LNAs) 812, filters 813, switches 814, and signal splitting/combining circuitry 815. However, other implementations are possible. One or more of the PAs 811 can include a load modulated power amplifier implemented in accordance with the teachings herein.

The front-end system 803 can provide a number of functionalities, including, but not limited to, amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 800 supports carrier aggregation, thereby providing flexibility to increase peak data rates. Carrier aggregation can be used for both Frequency Division Duplexing (FDD) and Time Division Duplexing (TDD) and may be used to aggregate a plurality of carriers or channels. Carrier aggregation includes contiguous aggregation, in which contiguous carriers within the same operating frequency band are aggregated. Carrier aggregation can also be non-contiguous and can include carriers separated in frequency within a common band or in different bands.

The antennas 804 can include antennas used for a wide variety of types of communications. For example, the antennas 804 can include antennas for transmitting and/or receiving signals associated with a wide variety of frequencies and communications standards.

In certain implementations, the antennas 804 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The mobile device 800 can operate with beamforming in certain implementations. For example, the front-end system 803 can include amplifiers having controllable gain and phase shifters having controllable phase to provide beam formation and directivity for transmission and/or reception of signals using the antennas 804. For example, in the context of signal transmission, the amplitude and phases of the transmit signals provided to the antennas 804 are controlled such that radiated signals from the antennas 804 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 804 from a particular direction. In certain implementations, the antennas 804 include one or more arrays of antenna elements to enhance beamforming.

The baseband system 801 is coupled to the user interface 807 to facilitate processing of various user input and output (I/O), such as voice and data. The baseband system 801 provides the transceiver 802 with digital representations of transmit signals, which the transceiver 802 processes to generate RF signals for transmission. The baseband system 801 also processes digital representations of received signals provided by the transceiver 802. As shown in FIG. 11, the baseband system 801 is coupled to the memory 806 of facilitate operation of the mobile device 800.

The memory 806 can be used for a wide variety of purposes, such as storing data and/or instructions to facilitate the operation of the mobile device 800 and/or to provide storage of user information.

The power management system 805 provides a number of power management functions of the mobile device 800. In certain implementations, the power management system 805 includes a PA supply control circuit that controls the supply voltages of the power amplifiers 811. For example, the power management system 805 can be configured to change the supply voltage(s) provided to one or more of the power amplifiers 811 to improve efficiency, such as power added efficiency (PAE).

As shown in FIG. 11, the power management system 805 receives a battery voltage from the battery 808. The battery 808 can be any suitable battery for use in the mobile device 800, including, for example, a lithium-ion battery.

### Applications

Some of the embodiments described above have provided examples in connection with mobile devices. However, the principles and advantages of the embodiments can be used for any other systems or apparatus that have needs for load modulated power amplifiers. Examples of such systems or apparatus include, but are not limited to, mobile phones, tablets, base stations, network access points, customer-premises equipment (CPE), laptops, and wearable electronics.

### Conclusion

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A load modulated power amplifier comprising:
an input terminal configured to receive a radio frequency signal and an output terminal configured to provide an amplified radio frequency signal;
a controllable capacitor;
a pair of amplifiers including a first amplifier and a second amplifier;
an output balun having a primary winding electrically connected between an output of the first amplifier and an output of the second amplifier and a secondary winding electrically connected between the output terminal and the controllable capacitor; and
an envelope control amplifier including an input transconductance stage configured to receive an envelope signal indicating an envelope of the radio frequency signal, a current feedback amplifier having an input electrically connected to an output of the input transconductance stage and an output configured to control the controllable capacitor, and a feedback resistor electrically connected between the output of the current feedback amplifier and the input of the current feedback amplifier.

2. The load modulated power amplifier of claim 1 wherein the envelope signal is differential, the input transconductance stage having a first input and a second input that differentially receive the envelope signal.

3. The load modulated power amplifier of claim 2 wherein the input transconductance stage provides a differential to single-ended conversion.

4. The load modulated power amplifier of claim 2 wherein the input transconductance stage includes a first input transistor having a gate electrically connected to the first input, a second input transistor having a gate electrically connected to the second input, a first resistor electrically connected between a source of the first input transistor and a tail node, and a second resistor electrically connected between a source of the second input transistor and the tail node.

5. The load modulated power amplifier of claim 1 wherein the current feedback amplifier includes an n-type input transistor having a source electrically connected to the input of the current feedback amplifier and a p-type input transistor having a source electrically connected to the input of the current feedback amplifier.

6. The load modulated power amplifier of claim 5 wherein the current feedback amplifier further includes a current mirror having an input electrically connected to a drain of the n-type input transistor.

7. The load modulated power amplifier of claim 6 wherein the current mirror includes a p-type mirror transistor having a drain electrically connected to the drain of the n-type input transistor, and a n-type mirror transistor having a gate electrically connected to the drain of the p-type mirror transistor and a source electrically connected to a gate of the p-type mirror transistor.

8. The load modulated power amplifier of claim 7 wherein the p-type mirror transistor is an enhancement-mode transistor, and the n-type mirror transistor is a depletion-mode transistor.

9. The load modulated power amplifier of claim 6 wherein the current feedback amplifier further includes a n-type output transistor having a gate electrically connected to an output of the current mirror and a source electrically connected to the output of the current feedback amplifier.

10. The load modulated power amplifier of claim 9 wherein a gate capacitance of the n-type output transistor serves as a frequency compensation capacitor for a feedback loop of the current feedback amplifier.

11. The load modulated power amplifier of claim 1 wherein the current feedback amplifier further includes a reference input configured to receive a reference voltage that controls a DC bias voltage of the input of the current feedback amplifier.

12. The load modulated power amplifier of claim 11 further comprising a digital-to-analog converter configured to generate the reference voltage based on a digital control signal.

13. The load modulated power amplifier of claim 11 wherein the current feedback amplifier includes a p-type input transistor, an n-type input transistor, a first gate bias circuit configured to bias a gate of the p-type input transistor based on the reference voltage, and a second gate bias circuit configured to bias a gate of the n-type input transistor based on the reference voltage.

14. The load modulated power amplifier of claim 1 further comprising a second feedback resistor electrically connected between a second output of the current feedback amplifier and the input of the current feedback amplifier, one of the feedback resistor or the second feedback resistor selectively activated based on a band select signal.

15. The load modulated power amplifier of claim 1 further comprising a driver amplifier having an input electrically connected to the input terminal and an input balun having a first winding electrically connected to an output of the driver amplifier and a second winding electrically connected between an input of the first amplifier and an input of the second amplifier.

16. The load modulated power amplifier of claim 1 further comprising a bias circuit configured to adjust a bias of at least one of the first amplifier or the second amplifier based on an output voltage of the envelope control amplifier.

17. A mobile device comprising:
a transceiver configured to generate a radio frequency signal; and
a front-end system including a load modulated power amplifier having an input terminal configured to receive the radio frequency signal and an output terminal configured to provide an amplified radio frequency signal, the load modulated power amplifier including a controllable capacitor, a pair of amplifiers including a first amplifier and a second amplifier, an output balun having a primary winding electrically connected between an output of the first amplifier and an output of the second amplifier and a secondary winding electrically connected between the output terminal and the controllable capacitor, and an envelope control amplifier including an input transconductance stage configured to receive an envelope signal indicating an envelope of the radio frequency signal, a current feedback amplifier having an input electrically connected to an output of the input transconductance stage and an output configured to control the controllable capacitor, and a feedback resistor electrically connected between the output of the current feedback amplifier and the input of the current feedback amplifier.

18-20. (canceled)

21. The mobile device of claim 17 wherein the current feedback amplifier includes an n-type input transistor having a source electrically connected to the input of the current feedback amplifier and a p-type input transistor having a source electrically connected to the input of the current feedback amplifier.

22. The mobile device of claim 21 wherein the current feedback amplifier further includes a current mirror having an input electrically connected to a drain of the n-type input transistor.

23-35. (canceled)

36. A method of amplification in a load modulation power amplifier, the method comprising:
amplifying a radio frequency signal received at an input terminal using a pair of amplifiers, the pair of amplifiers including a first amplifier and a second amplifier;
outputting an amplified radio frequency signal to a balun that incudes a primary winding electrically connected between an output of the first amplifier and an output of the
second amplifier, and a secondary winding electrically connected between an output terminal and a controllable capacitor;
receiving an envelope signal indicating an envelope of the radio frequency signal at an input transconductance stage of an envelope control amplifier;
controlling the controllable capacitor using an output of a current feedback amplifier of the envelope control amplifier, the input transconductance stage having an output electrically connected to an input of the current feedback amplifier; and
providing current feedback using a feedback resistor electrically connected between the output of the current feedback amplifier and the input of the current feedback amplifier.

37-51. (canceled)
